(19) United States
(12) Patent Application Publication
(10) Pub. No.: US 2012/0228634 A1
(43) Pub. Date: Sep. 13, 2012

(54) COMBINED SEMICONDUCTOR DEVICE

(75) Inventors: Akio SUGI, Matsumoto-city (JP); Tatsuhiko Fujihira, Matsumoto-city (JP)

(73) Assignee: FUJI ELECTRIC CO., LTD., Kawasaki (JP)

(21) Appl. No.: 13/409,627

(22) Filed: Mar. 1, 2012

(30) Foreign Application Priority Data
Mar. 7, 2011 (JP) 2011-049083

(51) Int. Cl. H01L 29/24

(52) U.S. Cl. 257/77; 257/E27.104

(57) ABSTRACT

A combined semiconductor device performs low conduction loss and low recovery loss characteristics suited to a circuit technology in a soft switching mode at a low cost. The device has a SJ-MOSFET and a wide band gap Schottky barrier diode connected in parallel to a built-in body diode in the SJ-MOSFET. The device includes a MOS type semiconductor element having a superjunction structure and a wide band gap Schottky barrier diode antiparallel-connected to the MOS type semiconductor element. The MOS type semiconductor element has a resistance section series-connected to a built-in body diode in the element. A resistance value of the resistance section is such a value that the forward voltage drop of the built-in body diode in the MOS type semiconductor element is higher than the forward voltage drop of the wide band gap Schottky barrier diode at a rated current of the MOS type semiconductor element.

### CROSS-REFERENCE TO RELATED APPLICATIONS

This application is based on, and claims priority to, Japanese Patent Application No. 2011-049083, filed on Mar. 7, 2011, in the Japanese Intellectual Property Office, the disclosure of which is incorporated herein by reference.

### BACKGROUND

1. Field

Embodiments of the present invention relate to a combined semiconductor device composed of a power switching element and a diode that are connected in parallel.

2. Description of the Related Art

Power supply circuits such as switching regulators and inverters need to be made highly efficient and miniaturized. One of the means therefor is reduction of losses in the power switching element used in the power supply circuit. Specific methods for loss reduction can include reduction of conduction losses by decreasing ON voltage of the switching element and reduction of switching losses by decreasing switching charges. These loss reduction means enhance circuit efficiency, and in addition, miniaturize the power supply circuit by decreasing the sizes of passive elements in the circuit by achieving high switching frequency. The term “switching element” in the following description includes a combined semiconductor device composed of a discrete semiconductor element and a diode connected in parallel to the semiconductor element.

A hard switching mode has conventionally been employed in which switching is conducted with high voltage and large current being applied to the switching element. The raising of switching frequency in this hard switching mode increases noise in the switching operation. This noise would cause avalanche breakdown of the switching element and the diode, and faults for example, breakdown of the element. In order to achieve the high efficiency and miniaturization without increasing the noise due to high switching frequency, a circuit technology of a soft switching mode in place of the hard switching mode, which causes the increased noise, has been developed as disclosed in Patent Document 1, for example. The circuit technology of the soft switching mode, in contrast to the hard switching mode, conducts switching operation in the state at substantially null applied voltage, and thus, achieves negligibly small switching loss and reduced switching noise.

Conventional power supply circuits have extensively used a vertical power MOSFET for a switching element in the circuits. The vertical power MOSFET is still used for a switching element in the power supply circuits of soft switching mode as before, and is a type of most frequently used switching element. Since the electric characteristics required for the switching element changes when the switching mode is changed to the soft switching mode, the circuit in the soft switching mode that employs a conventional vertical power MOSFET does not exploit its full performance. It is therefore demanded that the vertical power MOSFET be improved to exhibit electrical characteristics suited to the soft switching mode. The electrical characteristics required by the switching element suited to the soft switching mode includes low conduction loss (turn-on loss), low input gate capacitance, and low recovery loss. Meeting both the requirements of low conduction loss in the power MOSFET and low recovery loss in the parallel-connected diode is essential for reducing the overall conduction loss (turn-on loss) of the switching element because the conduction loss (turn-on loss) of the switching element is the sum of the conduction loss in the power MOSFET and the recovery loss in the parallel-connected diode.

Patent Document 2 discloses a switching element suited to the soft switching mode. In order to achieve the low conduction loss, this switching element has a SJ (super junction)-MOSFET structure exhibiting a low on-resistance characteristic. In order to achieve the low recovery loss, the switching element of Patent Document 2 further comprises a parallel-connected Schottky barrier diode that exhibits a forward voltage and a recovery loss lower than those of the built-in body diode in the SJ-MOSFET. In the switching element having this construction, most of the reverse current in the off-operation of the SJ-MOSFET is carried not by the built-in body diode but by the Schottky barrier diode. Therefore, the recovery loss in the turn-on process of the switching element is significantly reduced. Thus, the switching element has low on-resistance and low recovery loss characteristics suited to the soft switching mode.

Besides, a combined semiconductor device performing soft recovery characteristic is disclosed in Patent Document 3, in which a SJ-MOSFET and a Schottky barrier diode are formed monolithically in one substrate. Patent Document 3 states that the device achieves simultaneously, low on-resistance, high breakdown voltage, high-speed switching, and low noise.
Patent Document 1: Japanese Unexamined Patent Application Publication No. 2000-156978
Patent Document 2: Japanese Unexamined Patent Application Publication No. 2006-024690
Patent Document 3: Japanese Unexamined Patent Application Publication No. 2009-054961

The known techniques disclosed in the references, however, have the following problems. In the device of Patent Document 2, the lifetime is made short in order to raise the forward voltage of the built-in body diode in the SJ-MOSFET. This can be carried out, according to the document, by platinum diffusion, electron beam irradiation, proton irradiation, or combination of these means. However, these methods, which introduce lifetime killers, are generally costly and have a limitation in raising the forward voltage.

In the device of Patent Document 3, which comprises a SJ-MOSFET and a Schottky barrier diode formed monolithically in one substrate, the surface electrode needs to be fabricated by first depositing a barrier metal of titanium/titanium nitride lamination structure and then depositing an aluminum electrode. Hence, the electrode material cost is high.

### SUMMARY

Additional aspects and/or advantages will be set forth in part in the description which follows and, in part, will be apparent from the description, or may be learned by practice of the invention.

It is therefore an object of embodiments of the present invention to provide a combined semiconductor device exhibiting low conduction loss and low recovery loss performances suited to circuits of the soft switching mode. Embodiments of the invention allow a structure comprising a SJ-MOSFET and a Schottky diode that is connected in parallel to a built-in body diode in the SJ-MOSFET to be fabricated at a low cost.

In order to accomplish the above object, a combined semiconductor device according to embodiments of the invention comprises: (i) a MOS type semiconductor element including a superjunction structure, (a) comprising an n type drift layer in a structure repeating parallel-aligned p type columns and then type drift layer, the p type columns extending perpendicularly to a principal surface of a semiconductor substrate and aligned in parallel with each other p type column, (b) having such layer thicknesses and impurity concentrations of the first conductivity type drift layer and the second conductivity type columns that make a depletion layer rapidly expand in an off-period of the MOS type semiconductor element from each of parallel-aligned main pn junctions between the p type column and the n type drift layer into both sides of the pn junction until entire drift layer is depleted; and (c) comprising a resistance section series-connected to a built-in body diode in the MOS type semiconductor element having such a resistance value that makes a forward voltage drop of the built-in body diode be higher than a forward voltage drop of a wide band gap Schottky barrier diode at a rated current of the MOS type semiconductor element; and (ii) the wide band gap Schottky barrier diode antiparallel-connected to the MOS type semiconductor element.

Preferably, the resistance section is composed of a contact resistance between a drain electrode film and the semiconductor substrate of the MOS type semiconductor element.

Preferably, the resistance section is an n type semiconductor layer provided between a drain electrode film and the semiconductor substrate of the MOS type semiconductor element.

Preferably, the resistance section is a contact resistance between a drain electrode film and the semiconductor substrate of the MOS type semiconductor element, and an n type semiconductor layer provided between a drain electrode film and the semiconductor substrate of the MOS type semiconductor element.

Preferably, a semiconductor substrate for the wide band gap Schottky barrier diode is a silicon carbide semiconductor substrate.

Preferably, the MOS type semiconductor element is a MOSFET.

Embodiments of the present invention as stated above provide a combined semiconductor device exhibiting low conduction loss and low recovery loss performances suited to circuits of the soft switching mode. The embodiments of the invention allow a structure comprising a SJ-MOSFET and a Schottky diode that is connected in parallel to a built-in body diode in the SJ-MOSFET to be fabricated at a low cost.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a sectional view of an essential part of a combined semiconductor device of Example 1 according to embodiments of the present invention;

FIG. 2 shows forward current-voltage characteristics of a built-in diode and an SiC Schottky barrier diode in the device of Example 1 according to embodiments of the present invention; and

FIG. 3 is a sectional view of an essential part of a combined semiconductor device of Example 2 according to embodiments of the present invention.

### DESCRIPTION OF SYMBOLS

1: n type drift layer
2: p type column
3: p type base layer
4: n⁺⁺ type source region
5: n⁺⁺ type drain layer
6: drain electrode
7: source electrode
8: gate electrode
9: n type impurity layer
10: contact resistance
11: n type drift layer
12: gate insulation film
13: guard ring layer
15: n⁺⁺ type cathode
16: cathode electrode
17: anode electrode
21: drain
22: source
23: gate
31: SJ-MOSFET
32: Schottky barrier diode
50: SJ structure

### DESCRIPTION OF EMBODIMENTS

Now, some embodiments of a combined semiconductor device according to the present invention will be described in detail in the following with reference to the accompanying drawings. The invention should not be limited to the embodiments described in the following but includes variations and modifications as far as they do not exceed the scope and spirit of the invention.

### EXAMPLE 1

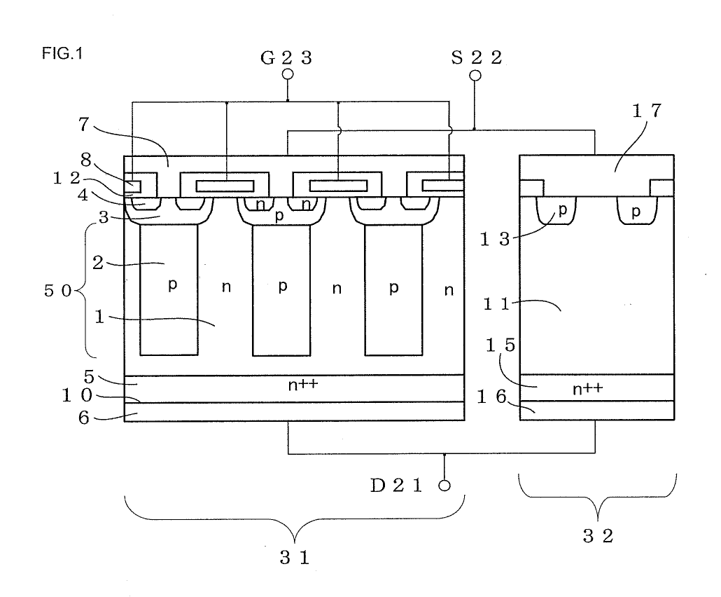

FIG. 1 is a sectional view of an essential part of a combined semiconductor device of Example 1 according to embodiments of the present invention. A SJ-MOSFET 31 as a MOS type semiconductor element comprises, from the back surface side, a drain electrode 6, an n⁺⁺ drain layer 5, and an n type drift layer 1. A SJ structure 50 is formed in the n type drift layer 1 repeating p type columns 2 interposing the n type drift layer 1 between the p type columns 2 arranged in the direction parallel to the principal surface of the semiconductor substrate. Each p type column 2 extends in the direction perpendicular to the principal surface of the semiconductor substrate. In the SJ structure 50, the thicknesses of layers and columns and impurity concentrations therein are so determined that when the SJ-MOSFET is subjected to a forward voltage, depletion layers rapidly expand from pn main junctions to make whole the drift layer depleted. Here, the forward voltage has a positive polarity at the drain electrode of the SJ-MOSFET and is a reverse voltage for the main pn junction. The depletion layers expands from each of the pn main junctions towards the drift layer 1 and the p type column 2 in the both sides of the pn main junction until whole the drift layer is thoroughly depleted. A p type base layer 3 is disposed at the top of each p type column 2 and electrically connecting to the p type column 2. An n⁺⁺ type source region 4 is disposed in the surface region of each of the p type base layer 3. A gate electrode 8 is provided over the surface of the p type base region 3 between the surface of the n⁺⁺ source region 4 and the surface of the n type drift layer 1 through a gate insulation film 12. Both the p type base layer 3 and the n⁺⁺source region 4 are made in electrical contact with a source electrode 7 at their surfaces. In addition in the featured construction of a device of embodiments of the invention, a contact resistance 10 is present between the drain electrode 6 and the n⁺⁺ drain layer 5. The contact resistance 10 composes a resistance section in the device of embodiments of the invention. The contact resistance 10 is necessarily so determined that the forward voltage in the built-in body diode in the SJ-MOSFET 31 at the rated current is higher than the forward voltage of the wide band gap Schottky barrier diode 32 that is described afterwards. Here, the built-in body diode is composed of n type regions of the n⁺⁺ drain layer 5 and the n type drift layer 1, and p type regions of the p type column 2 and the p type base layer 3.

The wide band gap type Schottky barrier diode 32 is a Schottky barrier diode fabricated using an SiC semiconductor and comprises, from the back surface, a cathode electrode 16, an n⁺⁺ type cathode layer 15, and an n type drift layer 11. The surface of the n type drift layer 11 is in Schottky contact with an anode electrode 17. A guard ring layer 13 is provided on the surface region of the n type drift layer 11 and made in electrical contact with the anode electrode 17. The wide band gap type Schottky barrier diode can be fabricated using a semiconductor material other than the SiC semiconductor substrate.

The built-in body diode in the SJ-MOSFET 31 and the wide band gap Schottky barrier diode 31 are connected in parallel in the same direction. The drain electrode 6 and the cathode electrode 16 are electrically connected to form a drain 21, D21. The source electrode 7 and the anode electrode 17 are electrically connected to form a source 22, S22. The gate electrodes 8 are connected at the same electric potential to form a gate 23, G23, which receives an input signal.

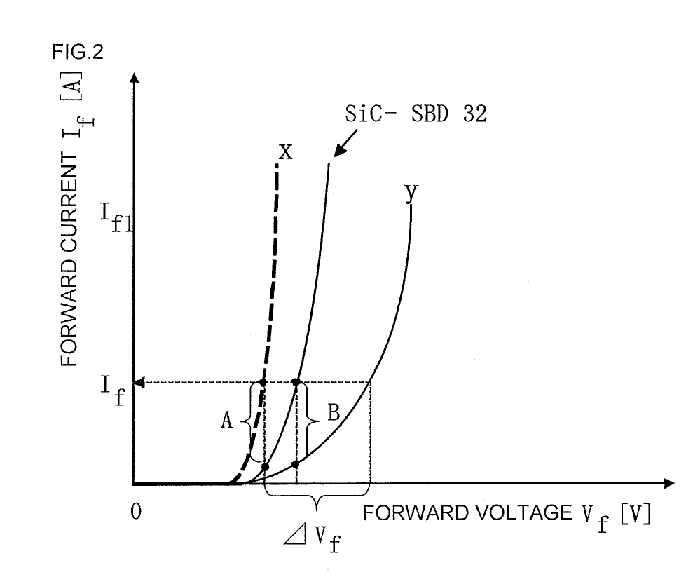

FIG. 2 shows forward voltage-current characteristics of the built-in body diode structure in the SJ-MOSFET 31. The figure compares forward output characteristics x and y of the built-in body diode in the SJ-MOSFET 31 for a relatively small contact resistance and a relatively large contact resistance interposed between the drain electrode 6 and the n⁺⁺ type drain layer 5, respectively. FIG. 2 also shows a forward output characteristic of the Schottky barrier diode 32 for comparison.

The contact resistance 10 interposed between the drain electrode 6 and the n⁺⁺ drain layer 5 is in series connection to the built-in body diode structure in the SJ-MOSFET 31, the built-in body diode structure being composed of n type regions of the n⁺⁺ drain layer 5 and the n type drift layer 1, and p type regions of the p type column 2 and the p type base layer 3. The contact resistance 10, therefore, suppresses current in the built-in body diode.

In the case of small contact resistance indicated by the curve x in FIG. 2, the forward voltage Vf of the built-in body diode in the SJ-MOSFET 31 is smaller than that of the SiC Schottky barrier diode 32 and thus, the most current flows through the built-in body diode in the SJ-MOSFET 31 as indicated by the symbol A in FIG. 2. In contrast, when the contact resistance is so determined that the forward voltage Vf of the built-in body diode in the SJ-MOSFET 31 is larger than that of the SiC Schottky barrier diode 32 as indicated by the curve y in FIG. 2, most current flows through the SiC Schottky barrier diode 32 as indicated by the symbol B in FIG. 2. Therefore, the current flowing in the built-in body diode in the SJ-MOSFET 31 is suppressed.

For a SJ-MOSFET 31 with a chip area of 0.2 cm² for example, a resistance of 50 mΩ is a proper value of the contact resistance 10. After the commonly employed manufacturing process for the front surface side structure of a SJ-MOSFET 31, the substrate is ground from the back surface to an appropriate thickness. To obtain an n⁺⁺ drain layer 5, phosphorous ions are injected to form a high impurity concentration layer with an impurity concentration of about 6×10¹⁸/cm³. The process of manufacturing a SJ-MOSFET 31 according to embodiments of the invention omits the plasma etching step of the silicon substrate that is usually conducted between the step of grinding the substrate from the back surface thereof and the step of ion implantation, or executes the plasma etching step with a reduced etching amount. This manufacturing process easily increases the contact resistance ten times larger than the process including the conventional plasma etching step. A contact resistance of 50 mΩ, for example, is easily obtainable.

In another method of producing the contact resistance, activation of the injected phosphorous ions is lowered by lowering the activation heat treatment temperature from a normal range of 370 to 420° C. down to a lower range of 300 to 370° C. The activation treatment step can entirely be eliminated.

The following describes an appropriate value of the contact resistance. For a SJ-MOSFET 31 of rating current of 20 A having a chip area of 0.2 cm², the voltage drop due to the contact resistance 10 of 50 mΩ is 20 A×50 mΩ=1.0V. The forward voltage drop Vf at the rating current of the SiC Schottky barrier diode 32 having a chip area of 0.06 cm² is about 1.5V; and the forward voltage drop (hereinafter also called simply a forward voltage) Vf of the built-in body diode in the SJ-MOSFET 31 is about 0.97V if the contact resistance is absent. Addition of the contact resistance of 50 mΩ to the built-in body diode in the SJ-MOSFET 31 results in the forward voltage Vf of the built-in body diode in the SJ-MOSFET 31 of 1.97V. This value of Vf is larger than the Vf of the SiC Schottky barrier diode 32 of 1.5V. Therefore, most of the current of 20 A flows in the SiC Schottky barrier diode 32 and the current flowing in the built-in body diode in the SJ-MOSFET 31 is suppressed.

The combined semiconductor device of Example 1 described above reduces the current in the built-in body diode without introducing lifetime killers. Therefore, the current flowing through the built-in body diode in the SJ-MOSFET 31 is suppressed at a lower cost as compared with conventional devices.

The main controlling element of the combined semiconductor device of Example 1 is the SJ-MOSFET. The main junctions of the SJ-MOSFET 31 have the SJ structure 50 in which a structure with parallel p type columns 2 sandwiching an n type drift layer 1 is repeated, as described previously. As a consequence, the pn junctions in the SJ structure 50 are main junctions and block a forward bias voltage on the switching element. The main junctions are forward-biased when the switching element is reverse-biased, and construct a built-in body diode. The area of the junctions of the built-in body diode is extremely large owing to the SJ structure 50. For example, the built-in body diode in the SJ-MOSFET 31 of Example 1 with a chip area of 0.2 cm² exhibiting a breakdown voltage of 600V has a junction area of 1.6 cm² which is eight times larger than the chip area in the case of a SJ structure 50 of a pitch of 6 μm and a junction depth of 40 μm. This junction area of 1.6 cm² is 27 times larger than the chip area of 0.06 cm² of the SiC Schottky barrier diode 32 in Example 1 according to embodiments of the invention as previously mentioned. Thus, in the device according to embodiments of the invention, most of the current in the off-state of the switching element flows in the SiC Schottky barrier diode 32 even through the SiC Schottky barrier diode has a very small actual junction area of 1/27 of that of the main element of SJ-MOSFET 31. Therefore, a switching element can be fabricated at a low cost. This is also true for Example 2 and Example 3 described in the following.

### EXAMPLE 2

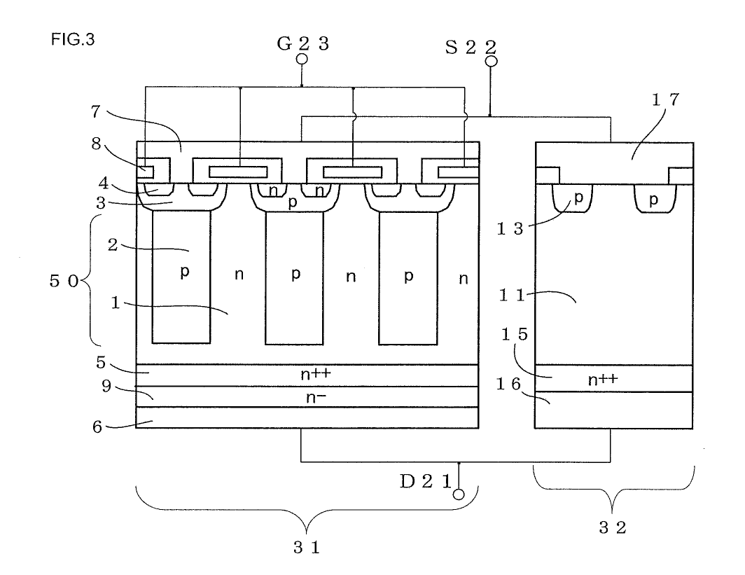

FIG. 3 is a sectional view of an essential part of a combined semiconductor device of Example 2 according to embodiments of the present invention. The device of FIG. 3 is different from the device of Example 1 shown in FIG. 1 in that the device of FIG. 3 has an n type impurity layer 9 with high resistivity inserted between the drain electrode 6 and the n⁺⁺ drain layer 5. The n type impurity layer 9 composes a resistance section in the device according to embodiments of the invention.

The effect of providing the high resistivity n type impurity layer 9 is equivalent to the effect of providing the relatively large contact resistance 10 in Example 1 of FIG. 1. The effect of both means is to raise the forward voltage in the built-in body diode without introducing lifetime killers, thereby reducing the current in the built-in body diode and increasing the forward current shared by the SiC Schottky barrier diode 32. As compared with the measure of forming the contact resistance 10 of Example 1, the measure of inserting the high resistivity n type impurity layer 9 can control the contact resistance value more easily since a desired resistance value can be obtained by adjusting the thickness or impurity concentration.

The following describes a layer construction and a process for obtaining the layer construction that are different from those of Example 1 in which the SJ-MOSFET 31 has a chip area of 0.2 cm² and a contact resistance 10 of 50 mΩ. Example 2 involves a construction and a process for obtaining the construction to provide a contact resistance of 50 mΩ, the construction being an n type impurity layer 9 with an impurity concentration lower than about 1×10¹⁷/cm³ inserted between the drain electrode 6 and the n⁺⁺ type drain layer 5. In the process of fabricating a device of Example 2 including the n type impurity layer 9, first a substrate for the n type impurity layer 9 and another substrate for the n⁺⁺ drain layer 5 are separately prepared and the two substrates are joined. Then, the joined substrates are ground leaving a thickness of 100 μm for the n type impurity layer 9. In the following steps, the structures above the n⁺⁺ type drain layer 5 on the n type impurity layer 9 are formed according to the ordinary process for fabricating a SJ-MOSFET The resistance of the resulting n type impurity layer 9 is about 4 mΩ, which is only 8% of the contact resistance.

The voltage drop due to the total resistance of 54 mΩ, which is the sum of the contact resistance 10 of 50 mΩ and the resistance of the n type impurity layer 9 of 4 mΩ, is 1.08V at the rating current of 20 A. If a Vf of 1.5V for the SiC Schottky barrier diode 32 and a Vf of 0.97V for the built-in body diode in the SJ-MOSFET 31 without the contact resistance are presumed similarly to in Example 1, the Vf of 2.05V results for the built-in body diode in the SJ-MOSFET 31 that is additionally provided with an n type impurity layer 9 with a low impurity concentration less than about 1×10¹⁷/cm³ beneath the n⁺⁺ drain layer 5 at the back surface of the built-in body diode in the SJ-MOSFET 31. The Vf value of 2.05V is larger than the Vf value of 1.5V for the SiC Schottky barrier diode 32. As a result, almost entire current of 20 A flows through the SiC Schottky barrier diode 32, to suppress the current in the built-in body diode in the SJ-MOSFET 31.

A combined semiconductor device of Example 2 as described above comprises, in addition to the contact resistance in Example 1, an n type impurity layer 9 with a low impurity concentration between the n⁺⁺ drain layer 5 and the drain electrode 6. This construction allows easy control of a relatively large contact resistance value.

### EXAMPLE 3

The semiconductor substrate for the Schottky barrier diode 32 is not limited to the SiC substrate, which is employed in Example 1 and Example 2, but can be selected from any other wide band gap semiconductor substrates. Example 3 employs a GaN semiconductor substrate. Construction and fabrication process of the Schottky barrier diode 32 using the GaN semiconductor substrate can be similar to those in Examples 1 and 2.

As described thus far referring to Examples 1, 2, and 3, embodiments of the present invention provide a combined semiconductor device having a Schottky barrier diode that is connected, in parallel, to a built-in body diode in a SJ-MOSFET, the combined semiconductor device exhibiting low recovery loss performance and being fabricated at a low cost.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A combined semiconductor device comprising:
a MOS type semiconductor element including a superjunction structure,
comprising a first conductivity type drift layer in a structure repeating parallel-aligned second conductivity type columns and the first conductivity type drift layer, the second conductivity type columns extending perpendicularly to a principal surface of a semiconductor substrate and aligned in parallel with each other second conductivity type column,
having such layer thicknesses and impurity concentrations of the first conductivity type drift layer and the second conductivity type columns that make a depletion layer rapidly expand in an off-period of the MOS type semiconductor element from each of parallel-aligned main pn junctions between the second conductivity type column and the first conductivity type drift layer into both sides of the pn junction until entire drift layer is depleted, and
comprising a resistance section series-connected to a built-in body diode in the MOS type semiconductor element having such a resistance value that makes a forward voltage drop of the built-in body diode be higher than a forward voltage drop of a wide band gap Schottky barrier diode at a rated current of the MOS type semiconductor element; and
the wide band gap Schottky barrier diode antiparallel-connected to the MOS type semiconductor element.

2. The combined semiconductor device according to claim 1, wherein the resistance section is composed of a contact resistance between a drain electrode film and the semiconductor substrate of the MOS type semiconductor element.

3. The combined semiconductor device according to claim 1, wherein the resistance section is a first conductivity type semiconductor layer provided between a drain electrode film and the semiconductor substrate of the MOS type semiconductor element.

4. The combined semiconductor device according to claim 1, wherein the resistance section is a contact resistance between a drain electrode film and the semiconductor substrate of the MOS type semiconductor element, and a first conductivity type semiconductor layer provided between a drain electrode film and the semiconductor substrate of the MOS type semiconductor element.

5. The combined semiconductor device according to claim 1, wherein a semiconductor substrate for the wide band gap Schottky barrier diode is a silicon carbide semiconductor substrate.

6. The combined semiconductor device according to claim 2, wherein a semiconductor substrate for the wide band gap Schottky barrier diode is a silicon carbide semiconductor substrate.

7. The combined semiconductor device according to claim 3, wherein a semiconductor substrate for the wide band gap Schottky barrier diode is a silicon carbide semiconductor substrate.

8. The combined semiconductor device according to claim 4, wherein a semiconductor substrate for the wide band gap Schottky barrier diode is a silicon carbide semiconductor substrate.

9. The combined semiconductor device according to claim 1, wherein the MOS type semiconductor element is a MOSFET.

10. The combined semiconductor device according to claim 2, wherein the MOS type semiconductor element is a MOSFET.

11. The combined semiconductor device according to claim 3, wherein the MOS type semiconductor element is a MOSFET.

12. The combined semiconductor device according to claim 4, wherein the MOS type semiconductor element is a MOSFET.

13. The combined semiconductor device according to claim 5, wherein the MOS type semiconductor element is a MOSFET.

14. The combined semiconductor device according to claim 6, wherein the MOS type semiconductor element is a MOSFET.

15. The combined semiconductor device according to claim 7, wherein the MOS type semiconductor element is a MOSFET.

16. The combined semiconductor device according to claim 8, wherein the MOS type semiconductor element is a MOSFET.
